(19) United States
(12) Patent Application Publication
(10) Pub. No.: US 2009/0072823 A1
(43) Pub. Date: Mar. 19, 2009

(54) 3D INTEGRATED COMPASS PACKAGE

(75) Inventors: Hong Wan, Plymouth, MN (US); Ryan W. Rieger, Brooklyn Center, MN (US); Michael J. Bohlinger, Minetonka, MN (US)

Correspondence Address: HONEYWELL INTERNATIONAL INC.;PATENT SERVICES AB-2B, 101 COLUMBIA ROAD, P.O. BOX 2245, MORRISTOWN, NJ, 07962-2245, US

(73) Assignee: Honeywell International Inc., Morristown, NJ (US)

(21) Appl. No.: 11/856,619

(22) Filed: Sep. 17, 2007

(51) Int. Cl. G01R 33/02

(52) U.S. Cl. 324/247

(57) ABSTRACT

A 3-axis sensor package with on-board sensor support chip on a single chip. In one aspect of the invention, a sensor package includes an X-axis sensor circuit component, a Y-axis sensor circuit component, or alternatively a combined X/Y-axis sensor circuit component, and a Z-axis sensor circuit component, each mounted to a top surface of a rigid substrate, or alternatively to a printed circuit board (PCB). The pads may be arranged in variety of designs, including a leadless chip carrier (LCC) design and a ball grid array (BGA) design. An application-specific integrated circuit (ASIC), or sensor support chip, is additionally mounted to the top surface of the rigid substrate. The sensor components and ASIC may be ball bonded or wire bonded to the substrate.

### BACKGROUND OF THE INVENTION

Magnetic sensors have been in use for well over 2,000 years, primarily used to sense the Earth's magnetic field for direction finding or navigation. Today, magnetic sensors are still a primary means of navigation and many other uses have evolved. As a result, magnetic sensors may be found in medical, laboratory, and electronic instruments, weather buoys, virtual reality systems, and a variety of other systems.

Modern consumer and commercial electronic equipment design has generally involved the consolidation of numerous disparate functions into a single device and the evolution of devices of increasingly diminutive scale. Small devices and devices that incorporate numerous functions require their internal components to be as small as possible. The desire to incorporate wayfinding and navigation technology into such compact devices requires the requisite 2- and 3-dimensional sensors, for example magnetic sensors and/or tilt sensors, to be of minimum height in the Z-axis (i.e., out of the plane of the PCB). Mounting a vertical sensor along the Z-axis is a challenge for the semiconductor assembly industry, especially for applications that have space limitations. One solution to mount vertical (Z-axis) sensors for applications with limited space and cost sensitive, high volume, standard PCB processes is given in U.S. patent application Ser. No. 11/022,495 titled “Single package design for 3-axis magnetic sensor,” to Bohlinger et al., and herein incorporated by reference.

### SUMMARY OF THE INVENTION

The present invention provides a 3-axis sensor with on-board sensor support chip on a single chip. In one aspect of the invention, a sensor package is provided comprising an X-axis sensor circuit component, a Y-axis sensor circuit component, or alternatively a combined X/Y-axis sensor circuit component, and a Z-axis sensor circuit component, each mounted to a top surface of a rigid substrate, or alternatively to a printed circuit board (PCB). The pads may be arranged in variety of designs, including a leadless chip carrier (LCC) design and a ball grid array (BGA) design. An application-specific integrated circuit (ASIC), or sensor support chip, is additionally mounted to the top surface of the rigid substrate. The sensor components and ASIC may be ball bonded or wire bonded to the substrate.

As can be appreciated, the invention offers a cost effective, miniature, signal-conditioned sensor by utilizing commercially available, low-cost assembly processes. The functionality of combined sensors and ASIC allows users to plug-and-play into their individual systems.

### BRIEF DESCRIPTION OF THE DRAWINGS

Preferred and alternative embodiments of the present invention are described in detail below with reference to the following drawings:

FIG. 1 is a schematic diagram of a sensor package comprising an X-Y-axis sensor, a Z-axis sensor, and an ASIC chip attached to a rigid substrate, according to the present invention;

FIG. 2 is a perspective view of a substrate with I/O pads and a Z-axis sensor, according to the present invention; and

FIG. 3 is a cross-sectional view of a substrate with solder-filled vias according to the present invention.

### DETAILED DESCRIPTION OF THE PREFERRED EMBODIMENT

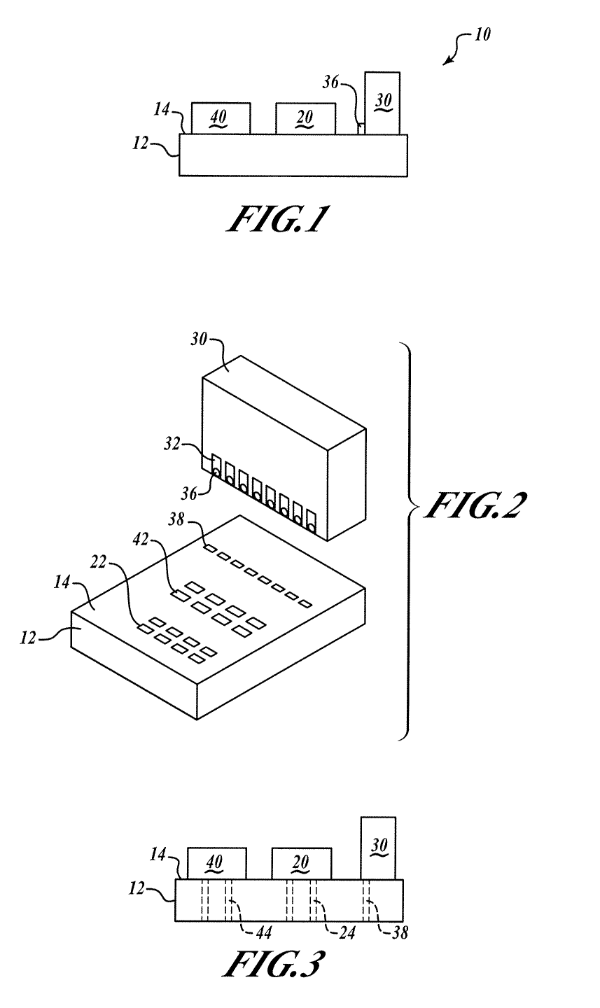

Referring to FIG. 1, there is illustrated the construction of a three-axis sensor package 10. The three-axis sensor package 10 includes a rigid substrate 12, which can be a printed circuit board (PCB), with a top surface 14 to which sensor circuit components including sensors 20 and 30, as well as an application-specific integrated circuit (ASIC) 40, are mounted and electrically connected via electrical traces 18 (FIG. 2) and input/output (I/O) pads on the substrate 12. The pads may be arranged in a variety of designs, including a leadless chip carrier (LCC) design with I/O pads along an outer perimeter of the substrate 12, and a ball grid array (BGA) design with I/O pads arranged in a grid in the center of the substrate 12, as shown in the Bohlinger application. The traces 18 can be on any surface of the package 10. The sensor 20 is sensitive to magnetic forces along the X-axis and the Y-axis, and the sensor 30 is sensitive to magnetic forces along the Z-axis. The package 10 can alternatively include sensors (not shown) for accelerometers, gyroscopes, or pressure sensors, with the sensors sensitive to the corresponding physical parameter.

The ASIC 40 provides support functions to the sensors 20, 30. The ASIC 40 can contain one or more of the following functions: amplification for sensor signal(s), analog to digital converter, digital interface (commonly SPI or I2C), control logic, measurement interrupts, field interrupts, programmable gain, temperature compensation, linearization, microprocessing, and power management. As related to magneto-resistive sensors, the ASIC can contain bias current drivers (not shown) and set field drivers (not shown). The bias current drivers may be used for conducting a self-test and/or used in field operations to eliminate stray fields, as well as for driving the device 10 to a known bias state in a closed-loop configuration. The set/reset drivers may be used to maximize sensitivity from the sensors and/or to remove sensor bias.

The components 20, 30, 40 are bonded to the substrate 12 via, for example, wire bonding, ball bonding, or tape automated bonding (TAB). Each component 20, 30, 40 can be mounted to the substrate 12 using a standard silicon chip assembly process. The X-Y-axis sensor 20 has input/output (I/O) pads (not shown), that conductively connect to corresponding I/O pads 22 on the substrate 12 (FIG. 2). The I/O pads 22 are in the form of solder-filled vias 24, which can extend completely through the substrate 12, as shown in FIG. 3, or can be blind or buried when the substrate 12 has more than two layers. The ASIC 40 is mounted in the same way to I/O pads 42 on the substrate 12. The I/O pads 42 can also include solder-filled vias 44.

The Z-axis sensor 30 is configured and oriented to be sensitive to magnetic forces along the Z-axis. The Z-axis sensor 30 includes I/O pads 32 including solder bumps 36 arranged in an array along only one edge of the sensor 30. The pads 32 conductively communicate with corresponding solder-filled metal pads 38 (via the solder bumps 36) extending completely through the substrate 12. In this way, a standard re-flow process can be used to make the Z-axis sensor 30 connection along with the X-Y-axis sensor 20; the connections can be performed in the same step or in different steps. With the components 20, 30, 40 all securely mounted to the substrate 12, the package can be encapsulated according to standard practices.

While the preferred embodiment of the invention has been illustrated and described, as noted above, many changes can be made without departing from the spirit and scope of the invention. For example, the wire bond pads and wires of the above-mentioned incorporated patent application can be incorporated into the invention. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A device comprising:
a rigid substrate having a top surface;
an application-specific integrated circuit (ASIC) attached to the top surface, including input/output (I/O) pads;
an X-axis sensor located on the top surface of the rigid substrate for sensing a physical parameter along an X-axis, the X-axis sensor including I/O pads and in electrical communication with the ASIC;
a Y-axis sensor located on the top surface of the rigid substrate for sensing the physical parameter along a Y-axis, the Y-axis sensor including I/O pads and in electrical communication with the ASIC;
a Z-axis sensor located on the top surface of the rigid substrate for sensing the physical parameter along a Z-axis, the Z-axis sensor including I/O pads and in electrical communication with the ASIC; and
corresponding I/O pads located on the top surface of the rigid substrate for conductively connecting to respective I/O pads on each sensor and ASIC.

2. The device of claim 1, further including an encapsulation layer around the package.

3. The device of claim 1 wherein the I/O pads of the Z-axis sensor are arranged in an array along an edge of the sensor and conductively connect with the corresponding I/O pads of the rigid substrate.

4. The device of claim 3, wherein the I/O pads of the Z-axis sensor are conductively connected to the rigid substrate by solder bumps.

5. The device of claim 4, wherein the I/O pads of the rigid substrate comprise solder-filled vias.

6. The device of claim 1, wherein the I/O pads of the substrate are arranged on an outer perimeter in a leadless chip carrier (LCC) design.

7. The device of claim 1, wherein the I/O pads of the rigid substrate are arranged in a grid in the center of the top surface of the substrate in a ball grid array design.

8. The device of claim 1, wherein the rigid substrate is a printed circuit board (PCB).

9. The device of claim 1, wherein the X-axis sensor and the Y-axis sensor are integrated into a single X-Y-axis sensor.

10. The device of claim 1, wherein the ASIC includes one of more than one circuit and more than one discrete component.

11. The device of claim 1, wherein the ASIC conditions a signal from at least one of the X-axis sensor, the Y-axis sensor, and the Z-axis sensor.

12. The device of claim 1, wherein the physical parameter is a magnetic field.

13. The device of claim 1, wherein the physical parameter is one of an acceleration, a pressure, and an orientation.
